(19) United States
(12) Patent Application Publication
(10) Pub. No.: US 2024/0149549 A1
(43) Pub. Date: May 9, 2024

(54) CUSHION STRUCTURE

(71) Applicant: NAN YA PLASTICS CORPORATION, TAIPEI (TW)

(72) Inventors: TE-CHAO LIAO, TAIPEI (TW); CHUN-CHE TSAO, TAIPEI (TW); SHIH-HSUN YEN, TAIPEI (TW)

(21) Appl. No.: 18/149,163

(22) Filed: Jan. 3, 2023

(30) Foreign Application Priority Data
Nov. 4, 2022 (TW) 111142125

(51) Int. Cl. B32B 5/06; B32B 5/02; B32B 5/18; B32B 5/24; B32B 5/26; B32B 7/02; B32B 25/10

(52) U.S. Cl. CPC B32B 5/06; B32B 5/02; B32B 5/18; B32B 5/245; B32B 5/26; B32B 7/02; B32B 25/10; B32B 2250/20; B32B 2250/40; B32B 2260/021; B32B 2260/046; B32B 2262/0253; B32B 2262/0269; B32B 2262/101; B32B 2262/103; B32B 2262/105; B32B 2262/106; B32B 2266/0207; B32B 2266/0214; B32B 2266/0235; B32B 2307/306; B32B 2307/536; B32B 2601/00

(57) ABSTRACT

A cushion structure is provided. The cushion structure includes a foaming middle layer and two composite fiber cloth layers. The foaming middle layer is disposed between the two composite fiber cloth layers. Each of the two composite fiber cloth layers is made of a heat-resistant cloth and a bulky yarn fiber cloth. The heat-resistant cloth is bonded to the bulky yarn fiber cloth through a needle-bonding process. A cushion rate of the cushion structure under thermocompression at a temperature of 190° C. is greater than 30%, and a recovery rate of the cushion structure under thermocompression at a temperature of 190° C. is greater than 95%.

### CROSS-REFERENCE TO RELATED PATENT APPLICATION

This application claims the benefit of priority to Taiwan Patent Application No. 111142125, filed on Nov. 4, 2022. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a cushion structure, and more particularly to a reusable cushion structure.

### BACKGROUND OF THE DISCLOSURE

In the process of manufacturing copper clad laminates (CCL) or multi-layered PCBs, a thermocompression machine is generally used for molding operations, and a thermocompression cushion is disposed between the machine and the laminate as a cushion in order to achieve the cushioning effect to protect the laminates.

With the trend of laminate thinning, the requirements for the flatness and uniformity of the laminate surface are also gradually increased, and the thermocompression cushion needs to have better cushioning properties and heat-resistant effects in order to retain competitiveness. In addition, in order to meet the requirements of environmental protection, in the relevant technical field, the usage count of the thermocompression cushion is expected to be increased so as to avoid waste.

Existing thermocompression cushions are generally made of kraft paper, or adhesives (such as rubber) that are joined to organic fibers or inorganic fibers (such as non-woven fabrics). However, the cushioning effect of the existing thermocompression cushions is limited, and the times of withstanding thermocompression are relatively low (approximately 200 times to 300 times). Therefore, it is expected to provide a thermocompression cushion in the market, which has good heat resistance and cushioning effect, and can be reused multiple times.

### SUMMARY OF THE DISCLOSURE

In response to the above-referenced technical inadequacies, the present disclosure provides a cushion structure.

In one aspect, the present disclosure provides a cushion structure. The cushion structure includes a foaming middle layer and two composite fiber cloth layers. The foaming middle layer is disposed between the two composite fiber cloth layers, each of the two composite fiber cloth layers is made of a heat-resistant fiber cloth and a bulky yarn fiber cloth, and the heat-resistant fiber cloth is bonded to the bulky yarn fiber cloth through a needle-bonding process.

A cushion rate of the cushion structure under thermocompression at a temperature of 190° C. is greater than 30%, and a recovery rate of the cushion structure under thermocompression at a temperature of 190° C. is greater than 95%.

In certain embodiments, bulky yarns in the bulky yarn fiber cloth are concentratedly arranged on multiple nodes of the heat-resistant fiber cloth, and the bulky yarn fiber cloth is a glass fiber bulky yarn fiber cloth.

In certain embodiments, two layers of the bulky yarn fiber cloth and one layer of the heat-resistant fiber cloth form a laminated unit, and the heat-resistant fiber cloth is disposed between the two layers of the bulky yarn fiber cloth.

In certain embodiments, a thickness ratio of the composite fiber cloth layers and the foaming middle layer ranges from 0.5 to 0.9.

In certain embodiments, the foaming middle layer is arranged on the composite fiber cloth layers through a thermocompression manner.

In certain embodiments, a foaming rate of the foaming middle layer ranges from 0.6 to 3.0.

In certain embodiments, a material of the foaming middle layer is selected from a group consisting of silicone rubber, fluororubber, polyvinylidene fluoride and polyetheretherketone.

In certain embodiments, the cushion structure further includes two surface reinforcement layers. The two surface reinforcement layers are respectively arranged on the two composite fiber cloth layers, so that the foaming middle layer and the two composite fiber cloth layers are disposed between the two surface reinforcement layers.

In certain embodiments, a material of the surface reinforcement layer is selected from a group consisting of polytetrafluoroethylene, polyvinylidene fluoride, fluororubber and polyetheretherketone.

Therefore, in the cushion structure provided by the present disclosure, by virtue of “the cushion structure having a foaming middle layer,” and “the composite fiber cloth layer being made of a heat-resistant fiber cloth and a bulky yarn fiber cloth,” the cushioning effect of the cushion structure and the usage count of thermocompression can be improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a cushion structure according to a first embodiment of the present disclosure,

FIG. 2 is a scanning electron micrograph of a cross-section of the cushion structure of the present disclosure,

FIG. 3 is a schematic cross-sectional view of a cushion structure according to a second embodiment of the present disclosure, and

FIG. 4 is a schematic top view of a cushion structure of the present disclosure during tests.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be disposed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

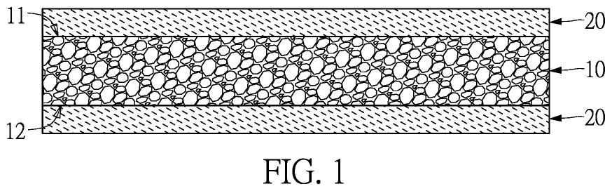

Referring to FIG. 1, in a first embodiment of the present disclosure, a thermoformed cushion structure for copper clad laminates or multi-layer PCBs is provided and is a three-layered structure. The cushion structure of the present disclosure has good cushioning properties, can withstand thermocompression of greater than 300 times (even up to 400 to 600 times), and is especially suitable for thermocompression processes under a temperature of 250° C.

As shown in FIG. 1, the cushion structure includes a foaming middle layer 10 and two composite fiber cloth layers 20. The foaming middle layer 10 and the two composite fiber cloth layers 20 can form an integrated structure by means of thermocompression. The foaming middle layer 10 has a first surface 11 and a second surface 12 opposite to each other, and the two composite fiber cloth layers 20 are disposed on the first surface 11 and the second surface 12, respectively.

In one exemplary embodiment, the foaming middle layer 10 is made of a foaming composition through a foaming process. The foaming composition includes: 100 to 80 parts by weight of a resin material, 10 to 5 parts by weight of a solvent, 0.1 to 1 part by weight of a foaming agent, and 0.1 to 3 parts by weight of thermally conductive particles. The solvent can be toluene, xylene, or small molecule silicone oil. The foaming agent can be an azo compound (for example: azobisisobutyronitrile), a hydrazide compound (e.g., p-toluenesulfonyl hydrazide (TSH)), a nitroso compound, or an amine compound (e.g., urea or ammonium bicarbonate). Alternatively, compressed gas or soluble gas may be introduced to physically perform foaming. The thermally conductive particles can be thermally conductive carbon black, thermally conductive graphite, nano-silicon magnesium nitride, nano-silicon carbide, nano-aluminum nitride, nano-boron nitride, high-purity spherical alumina, nano-silicon nitride, or a combination thereof, but the present disclosure is not limited thereto.

A resin material of the foaming middle layer 10 is selected from a group consisting of silicone rubber, fluororubber, polyvinylidene difluoride (PVDF), and polyetheretherketone (PEEK). In detail, a molecular weight of the resin material may range from 30,000 g/mol to 100,000 g/mol.

By adjusting a composition content of the foaming composition and parameters in the foaming process, a foaming rate of the foaming middle layer 10 can be controlled to be from 0.6 to 3.0, such as 0.7, 0.9, 1.1, 1.3, 1.5, 1.7, 1.9, 2.1, 2.3, 2.5, 2.7, or 2.9. If the foaming rate is too high, excessive air layers will reduce the heat conduction effect of the cushion structure, and a cushion rate of the cushion structure will have insufficient structural strength. If the foaming rate is too low, the cushion rate of the cushion structure cannot be effectively improved.

In one exemplary embodiment, a thickness of the foaming middle layer 10 ranges from 1.2 mm to 5 mm, such as 1.5 mm, 2.0 mm, 2.5 mm, 3.0 mm, 3.5 mm, 4.0 mm, or 4.5 mm. If the thickness of the foaming middle layer 10 is too thin, a cushioning effect of the cushion structure will be poor, and if the thickness of the foaming middle layer 10 is too thick, a thermocompression effect will be poor.

The composite fiber cloth layer 20 of the present disclosure is made of a heat-resistant fiber cloth and a bulky yarn fiber cloth (or called bulky fiber cloth). The heat-resistant fiber cloth can improve the heat resistance of the composite fiber cloth layer 20, thereby increasing usage count of thermocompression of the cushion structure. The heat-resistant fiber cloth can be combined with the bulky yarn fiber cloth by a needle-bonding process to integrally form a composite fiber cloth layer 20, so that the composite fiber cloth layer 20 is heat resistant, and has high cushioning and durability properties.

In detail, one layer of the heat-resistant fiber cloth is disposed between two layers of the bulky yarn fiber cloth, and the bulky yarn fiber cloth is used as a sandwich structure to stack and form into one laminated unit. In addition, according to the thickness of the heat-resistant fiber cloth or product requirements, several laminated units can be selected to be stacked and needle-bonded into the composite fiber cloth layer 20. That is, the composite fiber cloth layer 20 may include one or more laminated units.

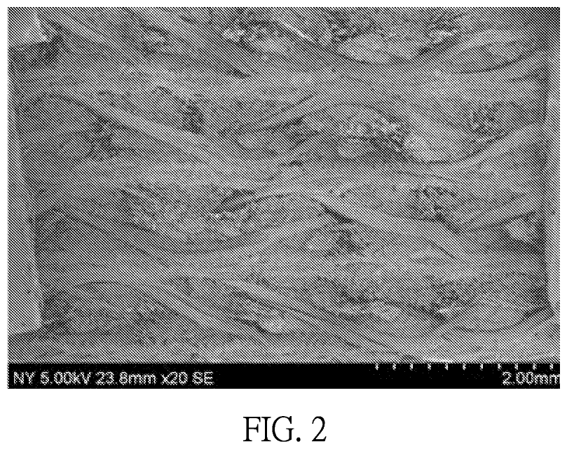

It can be found from the structure of the composite fiber cloth layer 20 that the bulky yarns of the bulky yarn fiber cloth are concentrated on multiple nodes of the heat-resistant fiber cloth (as shown in FIG. 2), which is a structure that cannot be formed by using plain weave fiber clothes. Therefore, compared with the plain weave fiber cloth, the composite fiber cloth layer 20 of the present disclosure has better durability and cushioning properties.

In detail, each composite fiber cloth layer 20 may include more than one layer of bulky yarn fiber cloth. By means of a needle-bonding process, multiple layers of bulky yarn fiber cloth and the heat-resistant fiber cloth can be combined to form an integrated structure to achieve better cushioning effect. Specifically, the bulky yarn fiber cloth may be a bulky yarn fiberglass cloth, but the present disclosure is not limited thereto.

The heat-resistant fiber cloth can be made of aramid fiber, poly-p-phenylene benzobisoxazole (PBO) fiber, polytetrafluoroethylene fiber, polyimide fiber, metal fiber, boron nitride fiber, ceramic fiber, etc., or graphite fiber.

In one exemplary embodiment, a basis weight of the composite fiber cloth layer 20 ranges from 300 g/cm³ to 900 g/cm³. A thickness of the composite fiber cloth layer 20 ranges from 0.5 mm to 1.5 mm, such as 0.6 mm, 0.8 mm, 1.0 mm, 1.2 mm, or 1.4 mm. If the thickness of the composite fiber cloth layer 20 is too thin, the cushioning effect of the cushion structure will be poor, and if the thickness of the foaming middle layer 10 is too thick, the thermocompression effect will be poor.

It is worth mentioning that in the present disclosure, the foaming middle layer 10 and the composite fiber cloth layer 20 containing the bulky yarn fiber cloth are particularly selected, so as to improve the durability of the cushion structure. Compared with the conventional cushion structure that only uses foam materials, the composite fiber cloth layer 20 provided by the present disclosure is used to match the foaming middle layer 10 having a specific thickness ratio, which can further improve the cushion rate and the recovery rate of the cushion structure. Therefore, the cushion structure can still have a good recovery rate after multiple instances of thermocompression.

Specifically, the present disclosure adjusts the thickness ratio of the composite fiber cloth layer 20 to the foaming middle layer 10 to be from 0.5 to 0.9, and preferably from 0.6 to 0.8. Under the thickness ratio, the composite fiber cloth layer 20 can further improve the recovery rate and the durability of the cushion structure.

When the thickness ratio of the composite fiber cloth layer 20 to the foaming middle layer 10 is lower than 0.5, the composite fiber cloth layer 20 cannot provide significant improvement to the cushion structure. When the thickness ratio of the composite fiber cloth layer 20 to the foaming middle layer 10 is higher than 0.9, a structural strength of the cushion structure will be too low such that the cushion structure is unsuitable for use.

### Second Embodiment

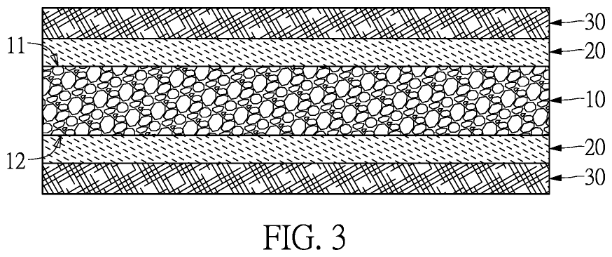

Referring to FIG. 3, in the second embodiment of the present disclosure, a thermoformed cushion structure for copper clad laminates or multi-layer PCBs is provided and is a five-layered structure. The cushion structure of the second embodiment is similar to that of the first embodiment, and the difference is that the cushion structure in the second embodiment further includes two surface reinforcement layers 30.

As shown in FIG. 3, a foaming middle layer 10 is disposed between two composite fiber cloth layers 20. The two surface reinforcement layers 30 can be respectively disposed on the two composite fiber cloth layers 20 to form an integrated structure by thermal lamination. That is to say, the two surface reinforcement layers 30 are the outermost layers of the cushion structure, and the foaming middle layer 10 and the two composite fiber cloth layers 20 are sandwiched between the two surface reinforcement layers 30.

The arrangement of the surface reinforcement layer 30 can improve the heat resistance effect of the cushion structure, and can also improve the flatness of the surface of the cushion structure. When the cushion structure of the present disclosure is used for a thermocompression laminate, a flatness of a thermocompression surface of the laminate can be maintained. In detail, the flatness of the surface of the laminate after thermocompression is greater than 90% (preferably from 91% to 97%), and the specific measurement method will be described later.

A material of the surface reinforcement layer 30 is selected from a group consisting of polytetrafluoroethylene, polyvinylidene fluoride, fluororubber, and polyetheretherketone.

In some embodiments, the surface reinforcement layer 30 may be formed by coating and then drying a resin composition. When the surface reinforcement layer 30 is formed by coating, a part of the resin composition penetrates into the composite fiber cloth layer 20. Therefore, after the surface reinforcement layer 30 is formed, the cushion structure can have better durability.

In some other embodiments, the surface reinforcement layer 30 may also be formed by thermally laminating a preformed film on the composite fiber cloth layer 20. During the thermally laminating process, a part of the surface reinforcement layer 30 will penetrate into the composite fiber cloth layer 20. Therefore, after the surface reinforcement layer 30 is formed, the cushion structure can have better durability.

For example, the surface reinforcement layer 30 can be formed by coating and then drying the fluororubber on the composite fiber cloth layer 20. Alternatively, the surface reinforcement layer 30 may also be formed by laminating polytetrafluoroethylene glass fiber cloth or polyvinylidene fluoride-impregnated cloth on the composite fiber cloth layer 20.

In one exemplary embodiment, a thickness of the surface reinforcement layer 30 ranges from 0.05 mm to 0.2 mm, such as 0.06 mm, 0.08 mm, 0.10 mm, 0.12 mm, 0.14 mm, 0.16 mm, or 0.18 mm. If the thickness of the surface reinforcement layer 30 is too thin, the effect of improving the surface flatness of the cushion structure is difficult to be achieved, and if the thickness of the surface reinforcement layer 30 is too thick, the thermocompression effect will be decreased.

In order to prove the advantages of the cushion structure provided by the present disclosure, the present disclosure provides the cushion structures of the first to third Examples and the first to third Comparative Examples respectively. In the first to third Experimental Examples and the first to third Comparative Examples, the foaming middle layer, the composite fiber cloth layer, and the surface reinforcement layer are prepared respectively according to the ingredients and conditions in Table 1, and then undergo thermocompression at a temperature of 230° C. and under a pressure of 30 kg/m², so as to obtain the cushion structures of the first to third Experimental Examples and the first to third Comparative Examples.

### First Experimental Example

A foaming composition is prepared, and the foaming composition includes 100 parts by weight of silicone rubber, 5 parts by weight of xylene and 0.1 parts by weight of a foaming agent. The foaming composition is used for foaming to prepare a foaming middle layer having a foaming rate of 2 and a thickness of 1.6 mm.

A layer of heat-resistant fiber is disposed between two layers of bulky yarn fiber cloth (the bulky yarn fiber cloth is used as a sandwich structure) as a laminated unit. A basis weight of the laminated unit is 800 g/cm² and a thickness of the laminated unit is 1.2 mm. The heat-resistant fiber cloth and the bulky yarn fiber cloth are combined to be a laminated unit by needle-bonded to obtain a composite fiber cloth layer.

Afterwards, according to the structure of the second embodiment, a PTFE fiberglass cloth, a composite fiber cloth layer, a foaming middle layer, a composite fiber cloth layer, and another PTFE fiberglass cloth are stacked in sequence to form a laminated structure, and the laminated structure is undergoes thermocompression at a temperature of 230° C. and under a pressure of 30 kg/m² to obtain a cushion structure.

### Second Experimental Example

The steps of the second Experimental Example are similar to those of the first Experimental Example, and the difference is that the foaming composition comprises 100 parts by weight of fluororubber, 5 parts by weight of xylene, and 0.2 parts by weight of a foaming agent. The foaming rate of the foaming middle layer is 1, and the thickness of the foaming middle layer is 1 is 2.2 mm.

A layer of heat-resistant fiber is disposed between two layers of bulky yarn fiber cloth (the bulky yarn fiber cloth is used as a sandwich structure) as a laminated unit. A basis weight of the laminated unit is 600 g/cm² and a thickness of the laminated unit is 0.9 mm. Two laminated units of the heat-resistant fiber cloth and the bulky yarn fiber cloth are stacked and undergo a needle-bonding process to obtain the composite fiber cloth layer.

Then, a PVDF impregnated cloth, a composite fiber cloth layer, a foaming middle layer, a composite fiber cloth layer, and another PVDF impregnated cloth are stacked in sequence to form a laminated structure, and the laminated structure undergoes thermocompression at a temperature of 230° C. and under a pressure of 30 kg/m² to obtain the cushion structure.

### Third Experimental Example

The steps of the third Experimental Example are similar to those of the first Experimental Example, and the difference is that the foaming composition comprises 100 parts by weight of polyetheretherketone, 5 parts by weight of xylene, and 0.5 parts by weight of a foaming agent. The foaming rate of the foaming middle layer is 0.8, and the thickness is 2.8 mm.

A layer of heat-resistant fiber is disposed between two layers of bulky yarn fiber cloth (using the bulky yarn fiber cloth as a sandwich structure) as a laminated unit. A basis weight of the laminated unit is 400 g/cm² and a thickness of the laminated unit is 0.6 mm Three laminated units of the heat-resistant fiber cloth and the bulky yarn fiber cloth are stacked and undergo a needle-bonding process to obtain the composite fiber cloth layer.

Then, a fluororubber layer, a composite fiber cloth layer, a foaming middle layer, a composite fiber cloth layer, and another fluororubber layer are stacked in sequence to form a laminated structure, and the laminated structure undergoes thermocompression at a temperature of 230° C. and under a pressure of 30 kg/m² to obtain the cushion structure. The fluororubber layer is formed of a fluororubber resin, and the fluororubber resin includes 100 parts by weight of fluororubber, 5 parts by weight of xylene, and 1 part by weight of a foaming agent.

### First Comparative Example

The steps of the first Comparative Example are similar to those of the first Experimental Example. The difference is that the foaming rate and the thickness of the foaming middle layer are different, the composite fiber cloth layer does not contain the bulky yarn fiber cloth, and the surface reinforcement layer of different materials is used.

In detail, the foaming composition in the first Comparative Example includes 100 parts by weight of silicone rubber, 5 parts by weight of xylene and 0.1 parts by weight of a foaming agent. The foaming composition is used for foaming to obtain a foaming middle layer having a foaming rate of 3 and a thickness of 1.3 mm. In addition, the composite fiber cloth layer in the first Comparative Example does not include the bulky yarn fiber cloth, and only includes a heat-resistant fiber cloth having a basis weight of 1000 g/cm² and a thickness of 1.5 mm.

### Second Comparative Example

The steps of the second Comparative Example are similar to those of the first Experimental Example, and the difference is that the foaming rate and the thickness of the foaming middle layer are different, the composite fiber cloth layer does not contain the bulky yarn fiber cloth, and the surface reinforcement layer of different materials is used.

In detail, the foaming composition in Comparative Example 2 includes 100 parts by weight of silicone rubber, 5 parts by weight of xylene, and 0.1 parts by weight of a foaming agent. The foaming composition is used for foaming to obtain a foaming middle layer having a foaming rate of 2.5 and a thickness of 1.6 mm. In addition, in Comparative Example 2, a plain weave fiber cloth is used as a sandwich structure, and one layer of heat-resistant fiber cloth is disposed between two layers of plain weave fiber cloth as a laminated unit. A basis weight of the laminated unit is 800 g/cm² and a thickness of the laminated unit is 1.2 mm A laminated unit of heat-resistant fiber cloth and the plain weave fiber cloth is combined in a needle-bonding process to obtain a composite fiber cloth layer.

Then, a Nomex® paper, a composite fiber cloth layer, a foaming middle layer, another composite fiber cloth layer, and another Nomex® paper are stacked in sequence to form a laminated structure, and the laminated structure undergoes thermocompression at a temperature of 230° C., and under a pressure of 30 kg/m² to obtain the cushion structure.

### Third Comparative Example

The steps of the third Comparative Example are similar to those of the first Experimental Example. The difference is that the foaming rate and thickness of the foaming middle layer are different, and the composite fiber cloth layer does not contain bulky yarn fiber cloth.

In detail, the foaming composition in the second Comparative Example includes 100 parts by weight of fluororubber, 5 parts by weight of xylene, and 0.1 parts by weight of a foaming agent. The foaming composition is used for foaming to obtain a foaming middle layer having a foaming rate of 2 and a thickness of 2.2 mm. In addition, in the third Comparative Example, a plain weave fiber cloth is used as a sandwich structure, and one layer of heat-resistant fiber cloth is disposed between two layers of the plain weave fiber cloth as a laminated unit. A basis weight of the laminated unit is 600 g/cm² and a thickness of the laminated unit is 0.9 mm Three laminated units of the heat-resistant fiber cloth and the plain weave fiber cloth are combined in a needle-bonding process to obtain a composite fiber cloth layer.

Then, the composite fiber cloth layer, the foaming middle layer, and another composite fiber cloth layer are stacked in sequence to form a laminated structure, and the laminated structure undergoes thermocompression at a temperature of 230° C. and under a pressure of 30 kg/m² to obtain the cushion structure.

TABLE 1

| | |
|---|---|
| Experimental Example | Comparative Example |

| | | 1 | 2 | 3 | 1 | 2 | 3 |
|---|---|---|---|---|---|---|---|
| Foaming | Resin | Silicone | Fluororubber | Polyetherether | Silicone | Silicone | Fluororubber |
| middle | material | rubber | | ketone | rubber | rubber | |
| layer | | | | [symbol] | [symbol] | | |
| | Foaming | 2 | 1 | 0.8 | 3 | 2.5 | 2 |
| | ratio | | | | | | |
| | Thickness | 1.6 | 2.2 | 2.8 | 1.3 | 1.6 | 2.2 |
| | (mm) | | | | | | |
| Composite | Sandwich | Bulky yarn | Bulky yarn | Bulky yarn | None | Plain weave | Plain weave |
| fiber cloth | structure | [symbol] | fiber cloth | fiber cloth | | fiber cloth | |
| layer | Cloth | | | | | | |

| | |
|---|---|
| material | Heat resistant fiber |

| | Thickness ratio of | | Laminate | |
|---|---|---|---|---|
| Surface | composite fiber cloth | Number | basis | Stack |
| reinforcement layer | layer/foaming middle | of | weight | thickness |
| Material | layer | layers | (g/cm²) | (mm) |
| PTFE fiberglass cloth | 0.75 | 1 | 800 | 1.2 |
| PVDF impregnated cloth | 0.82 | 2 | 600 | 0.9 |
| Fluororubber | 0.64 | 3 | 400 | 0.6 |
| Nomex ® paper | 1.15 | 1 | 1000 | 1.5 |
| Nomex ® knitted fabric | 0.75 | 1 | 800 | 1.2 |
| none | 1.23 | 3 | 600 | 0.9 |

Cushion structure

| | Laminate | |
|---|---|---|
| Thickness | basis weight | Thickness |
| (mm) | (g/cm²) | (mm ) |
| 4.36 | 1800 | 0.18 |
| 4.7 | 1400 | 0.35 |
| 4.3 | 1200 | 0.15 |
| 5 | 2300 | 0.35 |
| 4.7 | 1800 | 0.35 |
| 4 | 1400 | 0 |

[symbol]

indicates data missing or illegible when filed

In addition, the cushion structures of the first to third Experimental Examples and the first to third Comparative Examples undergo characteristic tests including usage count of thermocompression, cushion rate, recovery rate, heating rate, and flatness of the laminate after thermocompression, and the results of the tests are listed in Table 2.

Usage count of thermocompression is calculated by performing thermocompression at a temperature of 190° C. and under a pressure of 50 kg/m2, and when the cushion rate is lower than 30%, counting of the usage count of thermocompression is stopped.

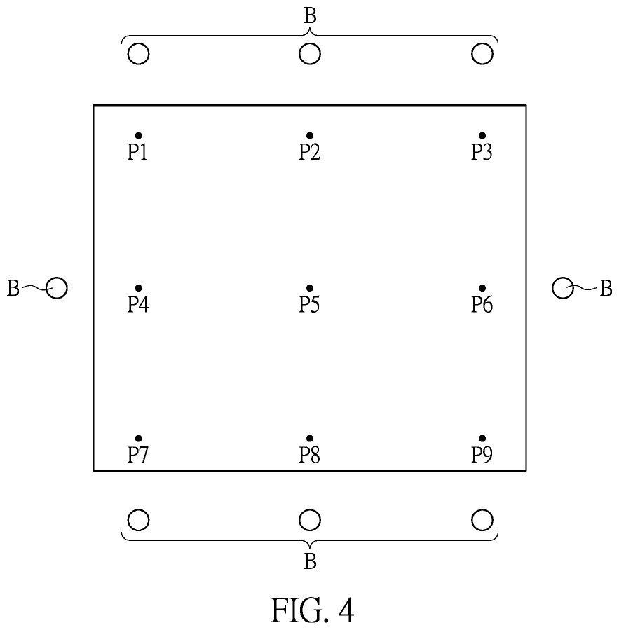

A manner in which cushion rate and recovery rate are tested can be referred to in FIG. 4. Nine positioning points (P1 to P9) are marked equidistantly on the cushion structure, and thickness of the cushion structure at the nine positioning points (P1 to P9) is measured and served as the thickness (A) before lamination. A lead block is disposed in proximity with the cushion structure, but is not in contact with the cushion structure. During a simulated lamination process, a temperature of the upper heating plate and the lower heating plate is raised to 190° C., the lamination process is performed with a pressure of 25 kg/cm³ for 30 minutes, and then the thickness of the cushion structure at nine positioning points (P1 to P9) is measured as the thickness (C) after lamination. Due to the disposition of the lead block, the upper heating plate presses down the cushion structure until the upper heating plate comes in contact with the lead block. Therefore, the thickness of the lead block is the thickness (B) of the cushion structure when the cushion structure is laminated.

In Table 2, a manner of calculating recovery rate and cushion rate is as follows:

Calculation formula of recovery rate=restoration rate/cushion rate;

Calculation formula of restoration rate=(thickness (C) after lamination−thickness (B) when laminated)/(thickness (C) after lamination);

Calculation formula of cushion rate=(thickness (A) before lamination−thickness (B) when laminated)/(thickness (A) before lamination).

In the experiment of measuring the heating rate, 60 sheets of glass fiber cloth (model 7628) are stacked as a simulated laminate. The cushion structure and the simulated laminate are disposed between the upper heating plate and the lower heating plate, the upper heating plate is in contact with the cushion structure, and the lower heating plate is in contact with the simulated laminate. A first material temperature line is set between the cushion structure and the glass fiber cloth, and a second material temperature line is set between the glass fiber cloth and the lower heating plate, so as to measure a heating rate of the glass fiber cloth during the simulated lamination process. Then, the temperature of the upper heating plate is raised to be 190° C., the temperature of the lower heating plate is controlled to be 30° C., and a pressure of 25 kg/cm³ is used to laminate for 10 minutes. Temperatures (T1, T2) displayed by the first material temperature line and the second material temperature line are recorded. The calculation formula of heating rate is as follows: calculation formula of heating rate=(temperature (T1) displayed by the first material temperature line−temperature (T2) displayed by the second material temperature line)/(10 minutes).

Regarding the test of the flatness of the laminate after thermocompression, the cushion structures of the above Experimental Examples 1 to 3 and Comparative Examples 1 to 3 are individually covered on the laminate for thermocompression. After the laminate is cooled to room temperature, the laminate is divided into nine regions, and the thicknesses of the nine fixed points respectively in each of the nine regions are measured. After an average is calculated, the flatness of the laminate after thermocompression can be obtained.

TABLE 2

| | Experimental Example | | | Comparative Example | | |
|---|---|---|---|---|---|---|
| | 1 | 2 | 3 | 1 | 2 | 3 |
| Usage count of thermo- | 500 | 500 | 450 | 350 | 400 | 400 |
| compression (times) | | | | | | |
| Cushion rate (%) | 35 | 38 | 36 | 18 | 20 | 20 |
| Recovery rate (%) | 97 | 99 | 98 | 94 | 92 | 93 |
| Heating rate | 12 | 11.6 | 12.3 | 11 | 11.5 | 10.8 |
| (° C./min) | | | | | | |
| Laminate flatness | 95 | 93 | 92 | 86 | 88 | 83 |
| after thermo- | | | | | | |
| compression (%) | | | | | | |

It can be known from the contents of Table 1 and Table 2 that the cushion structure of the present disclosure can withstand a high usage count of thermocompression, and has a high cushion rate (greater than 34%) and a high recovery rate (greater than 95%). When the cushion structure of the present disclosure is used for thermocompression, the heating rate of the laminate is relatively high (greater than 11.5° C./min), which can avoid prolonging the time of thermocompression. After thermocompression, the surface of the laminate can have good flatness (greater than 90%), and will not be affected by the thermocompression process, so that the cushion structure of the present disclosure is especially suitable for thin laminates.

Based on the content of the first Example and the first and second Comparative Examples, the cases in which silicon rubber is used as the foam material are compared with each other. When the composite fiber cloth layer only has the heat-resistant fiber cloth (the first Comparative Example), the cushion rate and the recovery rate are 18% and 94%, respectively, and the usage count of thermocompression is only 350 times. In order to increase the usage count of thermocompression, after using a plain weave fiber cloth to sandwich the heat-resistant fiber cloth (Comparative Example 2), the usage count of thermocompression is increased to 400 times and the cushion rate is increased to 20%, but the recovery rate of the overall cushion structure is reduced to 92%. In contrast, in Example 1, the bulky yarn fiber cloth is used to sandwich the heat-resistant fiber cloth and with the foaming middle layer having a specific thickness, the usage count of thermocompression, the cushion rate and the recovery rate of the cushion structure can be simultaneously increased.

### Beneficial Effects of the Embodiment

The beneficial effect of the present disclosure is that the cushion structure provided by the present disclosure can improve the cushioning effect of the cushion structure and the usage count of thermocompression by means of the technical solution of that “the cushion structure has a foaming middle layer” and “the composite fiber cloth layer is made of a heat-resistant fiber cloth and a bulky yarn fiber cloth”.

Furthermore, the cushion structure provided by the present disclosure further includes two surface reinforcement layers. The disposition of the surface reinforcement layers can improve the heat resistance effect of the cushion structure, and can improve the flatness of the cushion structure. In this way, during the thermocompression process, the laminate can reach the thermocompression temperature in a faster rate, and after thermocompression, the laminate can also have an improved flatness, which cannot be achieved by the conventional thermocompression cushion.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A cushion structure, comprising:
a foaming middle layer; and
two composite fiber cloth layers, wherein the foaming middle layer is disposed between the two composite fiber cloth layers, each of the two composite fiber cloth layers is made of a heat-resistant fiber cloth and a bulky yarn fiber cloth, and the heat-resistant fiber cloth is bonded to the bulky yarn fiber cloth through a needle-bonding process;
wherein a cushion rate of the cushion structure under thermocompression at a temperature of 190° C. is greater than 30%, and a recovery rate of the cushion structure under thermocompression at a temperature of 190° C. is greater than 95%.

2. The cushion structure according to claim 1, wherein bulky yarns in the bulky yarn fiber cloth are concentratedly arranged on multiple nodes of the heat-resistant fiber cloth, and the bulky yarn fiber cloth is a glass fiber bulky yarn fiber cloth.

3. The cushion structure according to claim 1, wherein two layers of the bulky yarn fiber cloth and one layer of the heat-resistant fiber cloth form a laminated unit, and the heat-resistant fiber cloth is disposed between the two layers of the bulky yarn fiber cloth.

4. The cushion structure according to claim 1, wherein a thickness ratio of the composite fiber cloth layers to the foaming middle layer ranges from 0.5 to 0.9.

5. The cushion structure according to claim 1, wherein the foaming middle layer is arranged on the composite fiber cloth layers through thermocompression.

6. The cushion structure according to claim 1, wherein a foaming rate of the foaming middle layer ranges from 0.6 to 3.0.

7. The cushion structure according to claim 1, wherein a material of the foaming middle layer is selected from a group consisting of silicone rubber, fluororubber, polyvinylidene fluoride, and polyetheretherketone.

8. The cushion structure according to claim 1, further comprising: two surface reinforcement layers, wherein the two surface reinforcement layers are respectively arranged on the two composite fiber cloth layers, so that the foaming middle layer and the two composite fiber cloth layers are disposed between the two surface reinforcement layers.

9. The cushion structure according to claim 8, wherein a material of the surface reinforcement layer is selected from a group consisting of polytetrafluoroethylene, polyvinylidene difluoride, fluororubber and polyetheretherketone.

10. The cushion structure according to claim 8, wherein a part of the surface reinforcement layer penetrates into the two composite fiber cloth layers.
